(19) United States
(12) Patent Application Publication
(10) Pub. No.: US 2015/0107639 A1
(43) Pub. Date: Apr. 23, 2015

(54) THREAD WITH A THERMOELECTRIC MATERIAL, METHOD FOR PRODUCING A COMPONENT FOR A THERMOELECTRIC MODULE AND TUBULAR THERMOELECTRIC MODULE

(71) Applicant: EMITEC GESELLSCHAFT FUER EMISSIONSTECHNOLOGIE MBH, Lohmar (DE)

(72) Inventors: ROLF BRUECK, BERGISCH GLADBACH (DE); WILFRIED MUELLER, LINDLAR (DE)

(21) Appl. No.: 14/582,454

(22) Filed: Dec. 24, 2014

Related U.S. Application Data
(63) Continuation of application No. PCT/EP2013/063289, filed on Jun. 25, 2013.

(30) Foreign Application Priority Data
Jun. 25, 2012 (DE) 102012105496.7

(51) Int. Cl. H01L 35/32; H01L 35/34

(52) U.S. Cl. CPC H01L 35/32; H01L 35/34
USPC 136/208; 438/54; 136/201

(57) ABSTRACT

A thread has an extent and at least partly includes a thermoelectric material. A method for producing a component for a thermoelectric module includes at least providing at least one thread having an extent, providing a tubular receptacle having an outer circumferential surface and winding the at least one thread around the tubular receptacle in such a way that at least one annular component for a thermoelectric module is formed on the outer circumferential surface. A tubular thermoelectric module is also provided.

### CROSS-REFERENCE TO RELATED APPLICATION

This is a continuation, under 35 U.S.C. §120, of copending International Application No. PCT/EP2013/063289, filed Jun. 25, 2013, which designated the United States; this application also claims the priority, under 35 U.S.C. §119, of German Patent Application DE 10 2012 105 496.7, filed Jun. 25, 2012; the prior applications are herewith incorporated by reference in their entirety.

### BACKGROUND OF THE INVENTION

### Field of the Invention

The present invention relates to a thread with a thermoelectric material, a method for producing a component for a thermoelectric module and a tubular thermoelectric module.

A thermoelectric module is suitable for generating electrical energy, for example from the exhaust gas of an internal combustion engine, by using a generator. That refers, in particular, to a generator for converting thermal energy of an exhaust gas into electrical energy, that is to say a so-called thermoelectric generator.

The exhaust gas from an internal combustion engine of a motor vehicle exhibits thermal energy which can be converted by using a thermoelectric generator into electrical energy, for example in order to charge a battery or some other energy storage device and/or supply the required energy directly to electrical consumers. In that way, the motor vehicle is operated with improved energy efficiency, and more energy is available for the operation of the motor vehicle.

A thermoelectric module has at least a plurality of thermoelectric elements. Thermoelectric materials are materials which can convert thermal energy into electrical energy (Seebeck effect) and vice versa (Peltier effect) in an effective manner. Thermoelectric elements include, for example, at least two semiconductor elements (p-doped and n-doped) which, at their mutually opposite ends which are respectively oriented toward a hot side and toward a cold side, are provided with bridges made of electrically conductive material in an alternating fashion. In a thermoelectric module, numerous such semiconductor elements are connected electrically in series. In order to ensure that the potential differences generated by the semiconductor elements in series do not cancel one another out, it is always the case that semiconductor elements with different majority charge carriers (n-doped and p-doped) are placed in direct electrical contact in alternating fashion. The electrical circuit can be closed, and electrical power thus tapped off, by using a connected load resistor.

It has already been attempted to provide corresponding thermoelectric modules for use in motor vehicles, in particular in passenger motor vehicles. They were, however, generally expensive to produce and distinguished by relatively low efficiency. It has thus heretofore not been possible to achieve suitability for mass production.

In particular, the methods for producing a thermoelectric module are complex and costly, because a multiplicity of components have to be assembled to form a thermoelectric module and correspondingly component tolerances have to be coordinated with one another.

### SUMMARY OF THE INVENTION

It is accordingly an object of the invention to provide a thread with a thermoelectric material, a method for producing a component for a thermoelectric module and a tubular thermoelectric module, which overcome the hereinafore-mentioned disadvantages and at least partially solve the highlighted problems of the heretofore-known devices and methods of this general type. In particular, the intention is to simplify the method for producing tubular thermoelectric modules by making it possible to reduce the number of parts and to reduce or even avoid the coordination of individual tolerances which has been required to date.

With the foregoing and other objects in view there is provided, in accordance with the invention, a thread having an extent and being at least partially formed of a thermoelectric material. The extent describes, in particular, the length of the thread. The thread is furthermore described by a diameter, which is defined as the (greatest) diameter of a cross section of the thread.

The thread can, in particular, be readily formed, wound, etc. (without the thermoelectric material). The thread can have a single-part or multi-part (e.g. with a plurality of fibers/filaments) configuration. If the thread has a multi-part configuration, this can also differ in portions, e.g. in that the number and/or configuration of the fibers/filaments is different in various thread sectors/portions.

The thread has, in particular, an extent which in technical terms is to be referred to as continuous. Continuous in this respect means that the thread has such an extent that it is regularly cut to length when used in a method for producing a (thermoelectric) component. In particular, the extent is at least 50 mm [millimeters], in particular at least 500 mm and preferably more than 1000 mm.

Fibers made of different materials can also be used in a thread. It is preferable that the thread is formed at least partially by at least one material selected from the following group:
ceramic material,
glass fiber material,
carbon fiber,
metallic material,
thermoelectric material.

The selection of the material of a fiber makes it possible to set the properties of the thread, in particular in the individual portions, in a manner oriented to the application. The thread can therefore have, in particular, the following properties (alone or else in combination): thermoelectric, electrically conductive, electrically insulating, thermally conductive, thermally insulating, sealing, and/or a high mechanical strength.

The following materials are used, in particular, as the thermoelectric material:

| Type: | Material: |
|---|---|
| V-VI | Bi₂Te₃ |
| IV-VI | PbTe |
| Zn₄Sb₃ | Zn₄Sb₃ |
| Silicides | p-MnSi_{1.73}; n-Mg₂Si_{0.4}Sn_{0.6}; Si_{0.80}Ge_{0.20}, Si_{0.94}Ge_{0.06} |
| Skutterudites | CoSb₃ |
| Semi-Heusler | TiNiSn |
| n/p-clathrates | Ba₈Ga₁₆Ge₃₀ |
| Oxides | p-NaCo₂O₄ |
| Zintl phases | p-Yb₁₄MnSb₁₁ |
| Th₃P₄ | La₃-XTe₄ |

According to a preferred embodiment, the thread includes different thermoelectric materials along the extent. In other words, this means, in particular, that at least two thread sectors including various thermoelectric materials are formed in the direction of the extent (in succession or adjacent one another). This applies, in particular, to the case in which the thread is still present as a starting element for the production of the thermoelectric component, i.e. in particular is subsequently also separated between the thread sectors. In particular, these different thermoelectric materials differ in terms of the temperature-dependent efficiency maxima. Every thermoelectric material has a characteristic optimum operating temperature, at which a maximum efficiency is achieved with regards to the conversion of thermal energy into electrical energy. It is possible for the thermoelectric materials of the thread sectors to be doped differently.

In accordance with another feature of the thread of the invention, the thread also includes non-thermoelectric material along the extent. In particular, this means that portions formed exclusively by non-thermoelectric material are provided along the extent. In particular, the thread has a plurality of portions including at least partially alternately thermoelectric material and non-thermoelectric material.

In accordance with a further particularly advantageous feature of the thread of the invention, the thread is (additionally) coated with the material (thermoelectric material, non-thermoelectric material) along the extent. This means, in particular, that a coating including the thermoelectric material and/or the non-thermoelectric material is provided in the thread or on the thread surface. If various materials are provided in an (individual) thread, these coatings are regularly provided not one on top of another, but rather alongside one another. The layer thickness can likewise vary, but this is not absolutely necessary. It is preferable that, proceeding from the thread surface, the layer thickness is such that a closed surface layer is formed, but the thread can still be deformed with the coating (which is possibly not yet permanently fixed).

In particular, the thread has at least one fiber, in particular a fiber having a tensile strength Rₘ of at least 200 N/mm².

In accordance with an added preferable feature of the thread of the invention, at least one of the fibers of the thread is coated with at least one material selected from the following group:
thermoelectric material,
non-thermoelectric material,
electrically insulating material,
electrically conductive material,
thermally insulating material,
thermally conductive material,
sealing material (with respect to gas and/or liquids).

The properties or material characteristics indicated in relative terms relate to the thermoelectric material used for converting thermal energy into electrical energy. This signifies, in particular, that “electrically insulating” means that the electrical conductivity of the material is lower than the electrical conductivity of the thermoelectric material. The same applies to “electrically conductive,” (in this case only higher) “thermally insulating,” “thermally conductive” and “sealing.”

In particular, the thread has different coatings in different portions, in particular it is coated with at least one material selected from the group specified above. Combinations of these properties or materials are also possible in individual portions. In particular, provision can be made for portions in which a material which is both electrically insulating and thermally insulating to be present as the coating.

In particular, the thread has a plurality of fibers, which are twisted with one another. The number of fibers can, for example, be 2 to 30, with the use of 2 to 10 fibers being preferred.

A twisted configuration of the fibers is present, in particular, when the fibers lie against one another along their extent and are entwined around one another. Twisting is understood to mean, in particular, the twisting of fibers against one another and/or the helical winding of fibers around one another.

It is preferable that at least two types of fibers having different properties are twisted with one another in the same portions of the thread. It is therefore possible to combine fibers having thermoelectric properties with fibers having non-thermoelectric and thermally insulating and also electrically insulating properties. The thread can be reinforced, in particular, by fibers having a high mechanical strength.

According to a particularly advantageous embodiment of the thread, the thread has cavities. The cavities may be configured in the manner of pores, for example. In this case, the cavities can be closed and/or connected to one another. It is regularly the case that the cavities are formed/delimited at least partially by the material of the thread or of the fiber. The cavities can be formed between fibers and/or in the fibers.

In particular, the cavities are filled at least partially with at least one material selected from the following group:
thermoelectric material,
non-thermoelectric material,
electrically insulating material,
electrically conductive material,
thermally insulating material,
thermally conductive material,
sealing material (with respect to gas and/or liquids).

It is preferable that the thread has different material characteristics at least in a radial direction or in the direction of the extent. Therefore, the thread can also have different material characteristics in both directions. In particular, different material characteristics are produced by the use of different materials and by the different structure of the thread and/or by a different treatment during the production of the thread. A treatment of this nature can include, for example, a thermal treatment and/or a treatment by pressure or the like (e.g. a sintering method).

In accordance with an additional particularly advantageous feature of the thread of the invention, the thread has, in particular, different cross-sectional areas in the direction of the extent. “Different” in this case means that the diameter or the size of the cross-sectional area varies in the direction of the extent. This variation can have a gradual and/or continuous form. By virtue of these different cross-sectional areas, it is also possible to produce very thin layers on the thermoelectric module, in such a way that, in particular, the entire thermoelectric module can also be produced at least partially from one or more of the proposed threads.

In accordance with yet another feature of the thread of the invention, the thread can be wound up on an outer circumferential surface of a tubular receptacle in a coil including a plurality of plies in a radial direction and can thereby form at least one annular, n-doped or p-doped thermoelectric semiconductor element, which can be disposed, together with other annular components, between an outer sleeve and an inner sleeve of a tubular thermoelectric module.

The thread will now be used additionally in conjunction with a preferred method for producing a component for a thermoelectric module.

With the objects of the invention in view, there is also provided a method for producing a component of a thermoelectric module, which comprises at least the following steps:
a) providing at least one thread having an extent,
b) applying thermoelectric material to the at least one thread,
c) providing a tubular receptacle having an outer circumferential surface, and
d) winding the at least one thread around the tubular receptacle, in such a way that at least one annular component for a thermoelectric module is formed on the outer circumferential surface.

An annular thermoelectric semiconductor element can be mentioned, in particular, as a component for a thermoelectric module. A plurality of such n-doped and p-doped semiconductor elements will be disposed alternately in succession at a later point and will be assembled with appropriate electrical interconnection to form a tubular thermoelectric module. The alternate electrical interconnection makes it possible for a temperature potential present on the thermoelectric module to be converted into an electric current. In addition to the thermoelectric components, it is also possible to produce electrically insulating or thermally insulating annular components, which are disposed between the thermoelectric components. Furthermore, it is also possible to produce electrically conductive and also thermally conductive components, which are used, for example, for the electrically conductive connection of the individual thermoelectric components.

The method is suitable, in particular, for producing at least individual components for a thermoelectric module and, in particular, also for producing an entire thermoelectric module having an individual thread or having a plurality of threads in succession and/or in parallel. In particular, provision is made for a (continuous) thread which has different materials and/or different properties in the same and/or individual portions.

The properties of the thread can, for example, be:
thermoelectric property for converting a temperature potential into an electric current,
electrically insulating, i.e. lower electrical conductivity [amperes/(volts*meters)] than the thermoelectric material,
electrically conductive, i.e. higher electrical conductivity [amperes/(volts*meters)] than the thermoelectric material,
thermally insulating, i.e. lower specific thermal conductivity [watts/(kelvin*meters)] than the thermoelectric material,
thermally conductive, i.e. higher specific thermal conductivity [watts/(kelvin*meters)] than the thermoelectric material,
high mechanical strength (in particular a tensile strength of more than 200 N/mm²),
sealing with respect to gas and/or liquids.

The definitions given herein for the terms “electrically insulating,” “electrically conductive,” “thermally insulating,” “thermally conductive” apply not only to the properties of the thread, but also to the coating, the fibers, the components and the materials disposed in the cavities.

In principle, the steps of the method can be carried out in the order denoted herein by letters, but this is not absolutely necessary. In particular, some or all of the steps can also be carried out at least at the same time. Thus, the thread can be removed, for example, from a coil (step a)), pulled through a coating bath (step c)) and conducted further to the receptacle, where it is wound up (steps b) and d)). It is also possible for the thread to be positioned on the receptacle without thermoelectric material and then for the thermoelectric material to be applied (e.g. into the thus formed cavities). It is furthermore possible to wind up the thread within a coating bath. Moreover, it is also possible for steps to be carried out repeatedly, if appropriate, for example the provision of a plurality of threads and/or receptacles and also, if appropriate, the repeated application of thermoelectric material (to various portions of the thread and/or at various points in time).

Step d) is preferably carried out in such a way that at least part of the outer circumferential surface of the receptacle is covered by the thread including thermoelectric material. In particular, a multi-ply coil is thereby formed with the thread outward in the radial direction, in such a way that the radial thickness of the annular component amounts to a multiple of the thread diameter. In this case, the coil can be provided with a plurality of threads and/or a different orientation.

In accordance with another particularly advantageous mode of the method of the invention, the tubular receptacle has at least one web which is at least partially circumferential or disposed around in a circumferential direction, in such a way that pockets, which are at least partially filled by the at least one thread, are formed in an axial direction on the outer circumferential surface of the tubular receptacle.

The tubular receptacle which is provided represents, in particular, the inner sleeve of a tubular thermoelectric module. In particular, however, the tubular receptacle is independent of the thermoelectric module to be produced, and therefore the annular component can be removed from the receptacle. The tubular receptacle serves, in particular, to provide an inner shape or form for the annular component, and therefore the at least one thread, proceeding from the tubular receptacle, produces the annular component successively in the radial direction and in the circumferential direction and also in an axial direction.

In particular, the webs are connected to the tubular receptacle in a form-locking manner or cohesively. In the case of a form-locking connection, one of the connecting partners is in the way of the other, i.e. it blocks the mobility thereof, for example by engagement. Cohesive connections refer to all connections in which the connecting partners are held together by atomic or molecular forces. In particular, depending on the progression of the winding in the axial direction, the webs are applied successively to the tubular receptacle.

The pockets, which in particular separate the individual annular components produced by the method from one another in the axial direction, are formed between the individual webs.

In accordance with a further mode of the method of the invention, it is possible to use a plurality of threads, or even different threads, which produce annular components in succession or at the same time in different or also identical pockets.

In accordance with an added mode of the method of the invention, a plurality of threads is provided and applied simultaneously to the tubular receptacle in a step d). In this case, the plurality of threads can include the same or different materials. Furthermore, the plurality of threads can at least partially have an identical structure.

In particular, the webs can be produced, for example, by electrically insulating threads, with a thermally insulating property of the thread being present at the same time, if appropriate. It is also possible that the thread being used has, in different portions, correspondingly different properties, in such a way that thermoelectric components, electrically insulating components, electrically conductive components, thermally insulating components, thermally conductive components or sealing components can be produced at previously stipulated points along the tubular receptacle. These different components can be produced and disposed alongside one another along the axial direction and/or along the circumferential direction and/or one on top of another in the radial direction.

In particular, the thus produced components can be fed to further method steps even only after partial production. These method steps can include, for example, a heat treatment and/or a pressure treatment (e.g. a sintering method). Furthermore, it is possible to introduce method steps for the application of a coating.

In accordance with an additional mode of the method of the invention, at least one thread made of a non-thermoelectric material is additionally concomitantly wound up. This can be provided, for example, for generating cavities and/or for setting a desired strength.

In accordance with yet another particularly advantageous mode of the method of the invention, step c) is performed at least partially at the same time as and/or after step d).

The thermoelectric material can be applied to the at least partially produced component, for example in the form of a coating, e.g. by a spraying method or by spreading on a pasty mass. If appropriate, further method steps follow and/or are performed in the meantime (thermal or pressure treatment).

In particular, for the method it is possible to use at least one thread which has different cross sections, in particular also in the direction of the extent. By virtue of these different cross sections, it is also possible to produce very thin layers on the thermoelectric module, in such a way that, in particular, the entire thermoelectric module can also be produced at least partially from one or more of the proposed threads.

With the objects of the invention in view, there is concomitantly provided a tubular thermoelectric module, at least comprising a cold side, a hot side and annular components disposed therebetween, wherein the components include at least one component selected from the group of:
at least one component including thermoelectric material,
at least one component including electrically insulating material,
at least one component including thermally insulating material,
at least one component including electrically conductive material,
at least one component including a sealing material,
at least one component including a thermally conductive material, and wherein furthermore the at least one annular component has been produced by a method proposed herein.

It is very particularly preferable that all of the annular components of the tubular thermoelectric module be formed with such a component including a thread. In this case, the tubular thermoelectric module preferably has an inner channel and an outer cylinder surface, around each of which either a hot or a cold medium can flow, in such a way that the annular components disposed therebetween are exposed internally and externally to a different temperature potential (hot side, cold side).

Other features which are considered as characteristic for the invention are set forth in the appended claims, noting that the features specified individually in the claims can be combined with one another in any desired technologically meaningful way and present further embodiments of the invention. In particular, the explanations in relation to the thread are equally applicable to the stated method for producing a component and also to the thermoelectric module, and vice versa. Advantageous embodiments of the invention and also the integration of the components (thus produced) in superordinate structural units (such as, for example, a thermoelectric module or a thermoelectric generator) are specified in the dependent claims.

Although the invention is illustrated and described herein as embodied in a thread with a thermoelectric material, a method for producing a component for a thermoelectric module and a tubular thermoelectric module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, elevational view of a thread having an extent;

FIG. 2 is a longitudinal-sectional view of a thread;

FIG. 3 is a cross-sectional view of the thread shown in FIG. 2;

FIG. 4 is an enlarged, cross-sectional view of a further thread;

FIG. 5 is an elevational view of a thread according to method step a);

FIG. 6 is a longitudinal-sectional view of a tubular receptacle according to method step b);

FIG. 7 is a longitudinal-sectional view of a tubular receptacle according to method steps c) and d);

FIG. 8 is a longitudinal-sectional view of a receptacle having webs after method step d);

FIG. 9 is a longitudinal-sectional view of a thermoelectric module; and

FIG. 10 is a perspective view of a thread with a variable cross-sectional area along an extent.

### DETAILED DESCRIPTION OF THE INVENTION

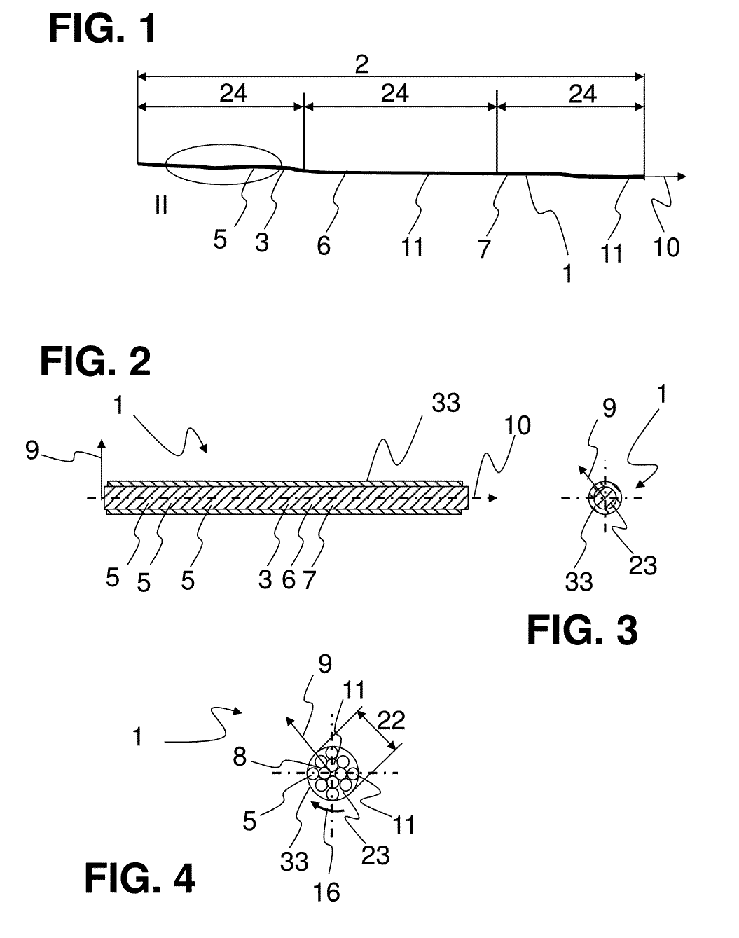

Referring now in detail to the figures of the drawing for explaining the invention and the technical field in more detail by showing particularly preferred structural variants to which the invention is not restricted and in which the same reference numerals are used to denote identical objects, and first, particularly, to FIG. 1 thereof, there is seen a thread 1 having a thread body with an extent 2. The thread 1 is subdivided along the extent 2 into a plurality of portions 24 (or thread sectors), which adjoin one another along a direction 10 of the extent 2. In the portion 24 on the left, the thread 1 includes or is formed of a thermoelectric material 3. In the portion 24 in the middle, the thread 1 includes or is formed of an electrically insulating material 6. In the portion 24 on the right, the thread 1 includes or is formed of a thermally insulating material 7. Different material characteristics 11 can be present in the different portions 24. The thread 1 is formed of at least one fiber 5. A section II is identified in the portion 24 on the left.

FIG. 2 shows the section II shown in FIG. 1 and the thread 1 (enlarged for illustration) in a longitudinal section. The thread 1 or the thread body extends in the direction of the extent 10 and is formed by a plurality of fibers 5 which are twisted with one another. In particular, the individual fibers 5 have different properties. In this case, the thread 1 is formed by fibers 5 made of thermoelectric material 3, made of electrically insulating material 6 and made of thermally insulating material 7. The fibers 5 are furthermore provided with a coating 33.

FIG. 3 shows the thread 1 or the thread body shown in FIG. 2 in a cross section 23. The thread 1 has a coating 33, which (completely) surrounds the fibers 5 of the thread 1 on the outside in the radial direction 9.

FIG. 4 shows a further thread 1 or thread body in a cross section 23. The thread has a (greatest) diameter 22. The thread 1 is formed by a plurality of fibers 5, which are disposed so as to be lying alongside one another in the cross section 23. Cavities 8, which are filled in this case by a coating 33, are formed by the fibers 5. The fibers 5 have different material characteristics 11, and therefore the thread 1 has different material characteristics 11 in the circumferential direction 16 and also in the radial direction 9.

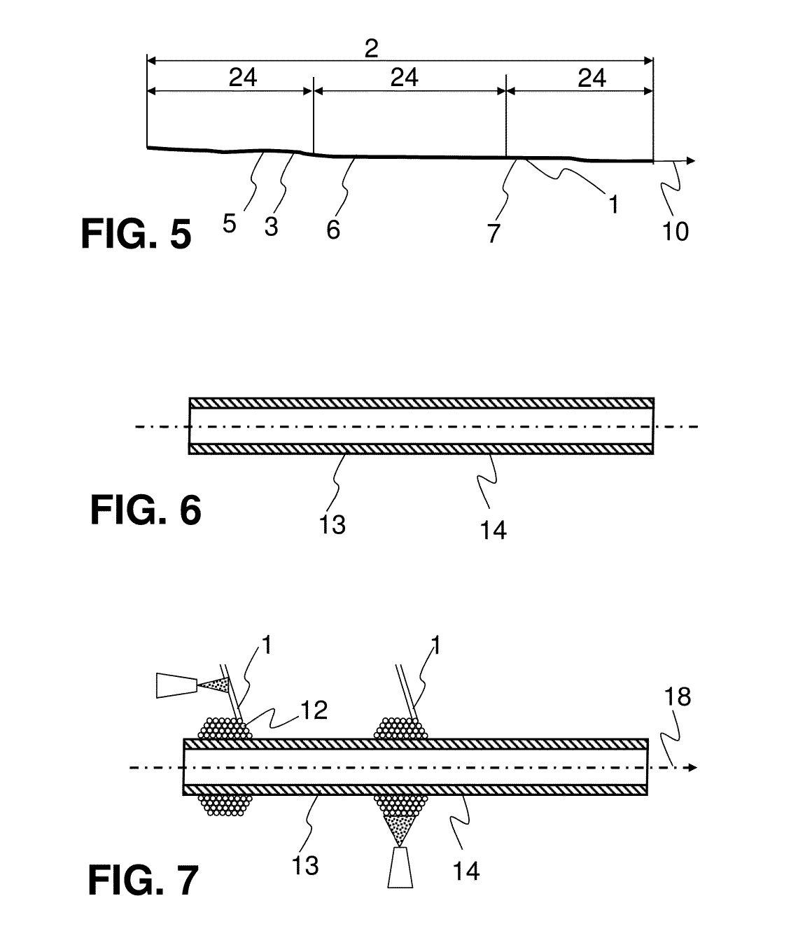

FIG. 5 shows step a) of the method, in which a thread 1 having a thread body with an extent 2 is provided. It can be seen that the thread 1 is divided into different portions 24 along the direction 10 of the extent 2. The thread 1 has different properties in each of these portions 24. In one portion 24, the thread 1 includes a thermoelectric material 3, and in other portions 24 it includes an electrically insulating material 6 and a thermally insulating material 7.

FIG. 6 shows step b) of the method, in which a tubular receptacle 13 having an outer circumferential surface 14 is provided.

FIG. 7 shows method steps c) and d), in which a plurality of threads 1 are wound around the tubular receptacle 13, in such a way that an annular component 12 is formed on the outer circumferential surface 14 of the receptacle 13. The annular components 12 are disposed in succession in an axial direction 18.

The application of the thermoelectric material can then be effected before, during and/or after the winding-up process, as is indicated therein by way of example by a spraying process at different points in time.

In particular, provision can be made for additional method steps which include, in particular, sintering method steps at elevated temperature and/or elevated pressure. This means, for example, that the configuration which is then present can be fed to a sintering process, in which, if appropriate, the thread configuration together with the material is compacted, hardened and/or thermally treated. In this case, pockets can, if appropriate, also be divided and treated separately.

It goes without saying that it is immediately apparent to a person skilled in the art that further (subordinate) processes can be integrated in this case, for example cutting the thread to length, disassembling the tubular receptacle, and the like.

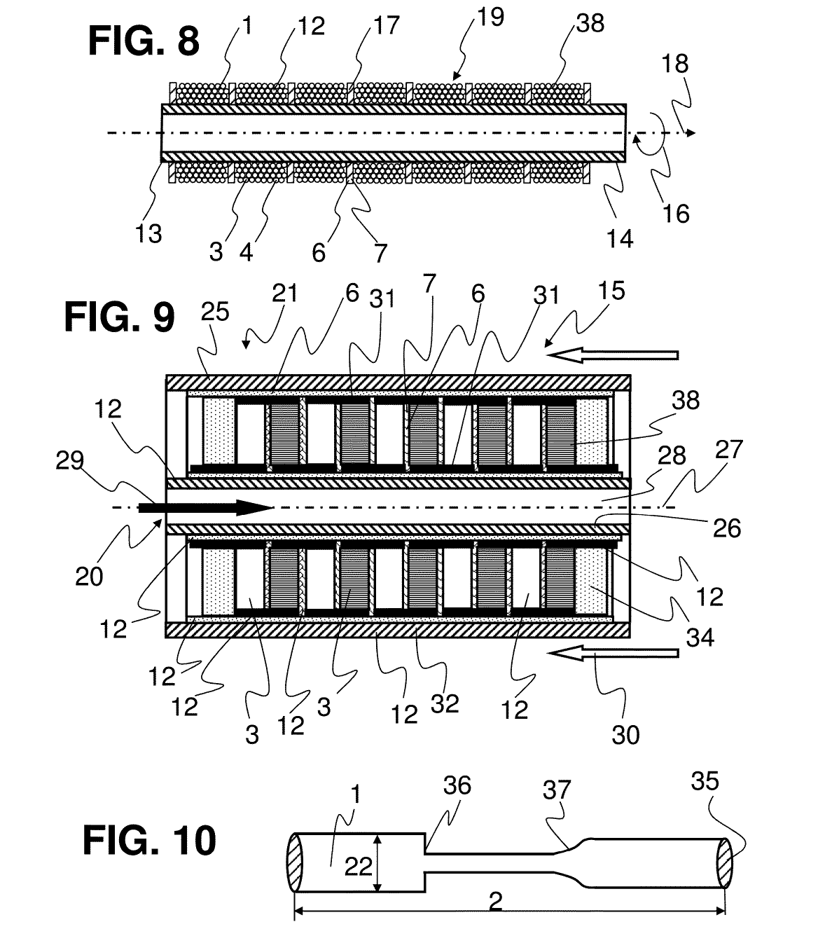

FIG. 8 shows a tubular receptacle 13 having webs 17, which extend in a circumferential direction 16 around the tubular receptacle 13. Pockets 19 are formed between the webs 17 and on the outer circumferential surface 14 by the webs 17. The pockets 19 are filled at least partially by the thread 1. The webs 17 are produced in this case from an electrically insulating material 6, and therefore the annular components 12 made of thermoelectric material 3 which are produced by the thread 1 can be disposed in a manner electrically insulated from one another in the axial direction 18. In this case, n-doped and p-doped thermoelectric material 3 is present, in particular, in adjacent pockets 19, and therefore annular n-doped and p-doped semiconductor elements 38 are formed in the pockets 19.

It is further shown therein that non-thermoelectric material 4 is also present in addition to the thermoelectric material 3 in the pockets 19. In particular, this non-thermoelectric material 4 has a lower electrical conductivity than the thermoelectric material 3 and similarly a lower thermal conductivity. The combination of thermoelectric material 3 and non-thermoelectric material 4 can influence the so-called “fill ratio” of the annular component 12. With regard to the fill ratio, reference is made to the entire contents of German Patent Application DE 10 2010 030 259 A1, which is incorporated herein by reference. With regard to the fill ratio, it is stated therein that the efficiency of a thermoelectric module is increased not solely by the greatest possible proportion of thermoelectric material between a hot side and a cold side, but also by the preservation of a maximum temperature potential between the hot side and the cold side.

The producible electrical power of the thermoelectric module is given, expressed in simplified terms, from the product of the thermoelectric efficiency of the module and the heat flow Q which arises on the hotter side of the thermoelectric module. In general, the thermoelectric efficiency increases with an increasing thermal resistance of the functional layer between the hot side and the cold side, since the temperature difference between the hot side and the cold side increases as a result. By contrast, the heat flow decreases due to the increased thermal resistance. This means, in particular, that the electrical power is a function of the thermal resistance of the thermoelectric module. The thermal resistance of the thermoelectric module is determined from the thermal conductivity of the semiconductor element (that is to say, in this case, the thermoelectric material 3 and the non-thermoelectric material 4), the geometric dimensions of the semiconductor elements, the thermal conductivity of the electrical insulation disposed between the semiconductor elements (e.g. in this case the webs 17), and the geometric dimensions thereof.

FIG. 9 shows a tubular thermoelectric module 15, which is formed by an inner sleeve 26 and an outer sleeve 25. The tubular thermoelectric module 15 extends along a central axis 27 and has a channel 28 inside the inner sleeve 26. It is shown therein that a coolant 29 flows through the channel 28 and that a hot fluid 30 flows over the outer sleeve 25. As a result, a hot side 21 of the thermoelectric module 15 is formed on the outer sleeve 25 and accordingly a cold side 20 of the thermoelectric module 15 is formed on the inner sleeve 26. However, the invention likewise encompasses the reversal of this configuration.

Annular components 12 made of at least the thermoelectric material 3 are disposed between the inner sleeve 26 and the outer sleeve 25 and are connected to one another alternately by electrically conductive material 31. In addition to the annular components 12 made of the thermoelectric material 3 (and if appropriate additionally the non-thermoelectric material 4), it is also possible, in particular, for all other components of the thermoelectric module 15 to be formed by correspondingly produced annular components 12. This applies, in particular, to the outer sleeve 25 and the inner sleeve 26, which are preferably formed from thermally conductive material 32, to the electrically insulating material 6 on the outer sleeve 25 and on the inner sleeve 26, to the electrically and thermally insulating material 6, 7 between the thermoelectric materials 3 (the semiconductor elements 38), to material 34 which outwardly seals the thermoelectric module 15, and to the electrically conductive material 31, which alternately connects the annular components 12 made of thermoelectric material 3 to one another.

FIG. 10 shows a thread 1 with a body having a variable cross-sectional area 35 along an extent 2. In this case, the diameter 22 or the size of the cross-sectional area 35 varies along the extent 2 in steps 36 or in the form of a continuous change 37.

A novel method for producing annular components and thermoelectric modules is proposed by the use of the specified thread. These thermoelectric modules can be produced in a cost-effective manner and without a large outlay for apparatus, since component tolerances are only to be taken into consideration in this case to a small extent.

In particular, instances of loading in the circumferential direction of a thermoelectric module, i.e., in particular, also stresses induced by instances of thermal expansion, are better compensated for or endured without failure through the use of a thread. The thread which is wound in the circumferential direction generates a high mechanical strength of the individual annular components and also of the thus produced thermoelectric module.

The annular components are not limited to a circular or oval structure, but instead polygonal, e.g. cuboidal, components can equally also be produced. In particular, the annular components produced according to the invention can be combined with annular components produced conventionally from sintered material or solid material.

1. A thread, comprising:
a thread body;
said thread body having an extent and at least partially including a thermoelectric material.

2. The thread according to claim 1, wherein said thread body includes at least different thermoelectric materials or non-thermoelectric material along said extent.

3. The thread according to claim 2, wherein said thread body is coated with said material along said extent.

4. The thread according to claim 1, wherein said thread body has at least one of:
at least one fiber having a tensile strength of at least 200 N/mm²;
a plurality of fibers being twisted with one another;
different material characteristics at least in a radial direction or in a direction of said extent; or
cavities being filled at least partially with at least one material selected from the following group:
thermoelectric material,
electrically insulating material,
electrically conductive material,
thermally insulating material,
thermally conductive material,
sealing material.

5. The thread according to claim 1, wherein said thread body has different cross-sectional areas in a direction of said extent.

6. The thread according to claim 1, wherein said thread body is configured to be wound up on an outer circumferential surface of a tubular receptacle in a coil including a plurality of plies in a radial direction, to thereby form at least one annular, n-doped or p-doped thermoelectric semiconductor element to be disposed, together with other annular components, between an outer sleeve and an inner sleeve of a tubular thermoelectric module.

7. A method for producing a component for a thermoelectric module, the method comprising the following steps:
a) providing at least one thread having an extent;
b) providing a tubular receptacle having an outer circumferential surface;
c) applying thermoelectric material to the at least one thread; and
d) winding the at least one thread around the tubular receptacle forming at least one annular component for a thermoelectric module on the outer circumferential surface.

8. The method according to claim 7, which further comprises placing at least one web at least partially around the tubular receptacle in a circumferential direction, forming pockets at least partially filled by the at least one thread in an axial direction on the outer circumferential surface of the tubular receptacle.

9. The method according to claim 7, which further comprises simultaneously applying the at least one thread as a plurality of threads to the tubular receptacle in a step d).

10. The method according to claim 7, which further comprises concomitantly winding up at least one thread made of a non-thermoelectric material.

11. The method according to claim 9, which further comprises carrying out step c) at least partially at the same time as or after step d).

12. A tubular thermoelectric module, comprising:
a cold side;
a hot side; and
annular components disposed between said cold side and said hot side,
said annular components each including a tubular receptacle having an outer circumferential surface, at least one thread having an extent and being wound around said outer circumferential surface, and at least one of:
thermoelectric material,
electrically insulating material,
thermally insulating material,
electrically conductive material,
thermally conductive material, or
sealing material.

13. The tubular thermoelectric module according to claim 12, which further comprises at least one web disposed at least partially around said tubular receptacle in a circumferential direction, forming pockets at least partially filled by said at least one thread in an axial direction on said outer circumferential surface of said tubular receptacle.
